(19) United States
(12) Patent Application Publication
(10) Pub. No.: US 2015/0325514 A1
(43) Pub. Date: Nov. 12, 2015

(54) HIGH DENSITY SRAM ARRAY DESIGN WITH SKIPPED, INTER-LAYER CONDUCTIVE CONTACTS

(71) Applicant: QUALCOMM Incorporated, San Diego, CA (US)

(72) Inventors: Niladri Narayan MOJUMDER, San Diego, CA (US); Zhongze WANG, San Diego, CA (US); Stanley Seungchul SONG, San Diego, CA (US); Choh Fei YEAP, San Diego, CA (US)

(73) Assignee: QUALCOMM Incorporated, San Diego, CA (US)

(21) Appl. No.: 14/274,378

(22) Filed: May 9, 2014

(51) Int. Cl. H01L 23/522; H01L 21/768; H01L 27/11

(52) U.S. Cl. CPC H01L 23/5226; H01L 27/1104; H01L 21/76895

(57) ABSTRACT

A static random access memory (SRAM) cell includes a first conductive layer including a wordline landing pad extending into a neighboring memory cell in an adjacent row of a memory array. The wordline landing pad in the first conductive layer is electrically isolated from all gate contacts of the neighboring memory cell. The SRAM cell also includes a second conductive layer including a wordline coupled to the wordline landing pad in the first conductive layer. The SRAM cell further includes a first via coupling a gate contact of a pass transistor gate in the SRAM cell to the wordline landing pad in the first conductive layer. The SRAM cell also includes a second via coupling the wordline landing pad and the wordline of the second conductive layer.

### TECHNICAL FIELD

The present disclosure generally relates to static random access memory (SRAM) design and fabrication. More specifically, the present disclosure relates to a high density SRAM array design with skipped, inter-layer conductive contacts.

### BACKGROUND

Semiconductor memory devices include, for example, a static random access memory (SRAM) and a dynamic random access memory (DRAM). A DRAM memory cell generally includes one transistor and one capacitor, thereby providing a high degree of integration. DRAM, however, requires constant refreshing, which limits the use of DRAM to computer main memory. An SRAM memory cell, by contrast, is bi-stable, meaning that it can maintain its state statically and indefinitely, so long as adequate power is supplied. SRAM also supports high speed operation, with lower power dissipation, which is useful for computer cache memory.

To continue SRAM scaling, SRAM bit cell layouts should be designed to allow higher density, higher yield and lower production costs. One example of an SRAM memory cell is a six transistor (6T) SRAM memory cell that includes, for example, six metal-oxide-semiconductor (MOS) transistors. As processes for fabricating MOS devices migrate to smaller and smaller nanometer technologies, the use of conventional 6T SRAM cells within processor cache memories prohibits compliance with performance specifications, decreases process margin, and increases manufacturing costs. Furthermore, SRAM designs may employ conductive layers that violate minimum conductive area scaling rules. That is, certain conductive layers may be considered too small to properly manufacture with desired reliability.

### SUMMARY

A static random access memory (SRAM) cell includes a first conductive layer including a wordline landing pad extending into a neighboring memory cell in an adjacent row of a memory array, the wordline landing pad in the first conductive layer being electrically isolated from all gate contacts of the neighboring memory cell. The SRAM cell also includes a second conductive layer including a wordline coupled to the wordline landing pad in the first conductive layer. The SRAM cell further includes a first via coupling a gate contact of a pass transistor gate in the SRAM cell to the wordline landing pad in the first conductive layer. The SRAM cell also includes a second via coupling the wordline landing pad and the wordline of the second conductive layer.

A method of fabricating a semiconductor device includes fabricating a pass transistor and a neighbor transistor that is adjacent to the pass transistor on a substrate, the pass transistor and the neighbor transistor both containing a gate contact. The method also includes fabricating a first via on the gate contact that is on a pass transistor gate. The method further includes forming a first conductive layer on the first via that overlaps both the pass transistor and the neighbor transistor. The method also includes fabricating a second via on the first conductive layer. The method further includes fabricating a first wordline on the second via and a second wordline aligned with the neighbor transistor.

A static random access memory (SRAM) cell includes a first conductive layer including a wordline landing pad extending into a neighboring memory cell in an adjacent row of a memory array, the wordline landing pad in the first conductive layer being electrically isolated from all gate contacts of the neighboring memory cell. The SRAM cell also includes a second conductive layer including a wordline coupled to the wordline landing pad in the first conductive layer. The SRAM cell further includes a first means for coupling a gate contact of a pass transistor gate in the SRAM cell to the wordline landing pad in the first conductive layer. The SRAM cell also includes a second means for coupling the wordline landing pad and the wordline of the second conductive layer.

This has outlined, rather broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIGURE lA shows a schematic of a conventional six transistor (6T) SRAM memory cell.

FIG. 1B shows a layout view of a conventional 6T SRAM memory cell.

FIG. 2 shows a layout view of an SRAM memory cell design according to an aspect of the disclosure.

FIG. 3 shows a cross-sectional view of an SRAM memory cell design according to an aspect of the disclosure.

FIGS. 4A-4B show merged wordline pads and vias from layout views of SRAM memory cell designs according to aspects of the disclosure.

FIGS. 5A-5C show wordlines, vias and conductive gates from layout views of SRAM memory cell designs according to aspects of the disclosure.

FIG. 6 is a process flow diagram illustrating a process of fabricating an SRAM memory cell design according to an aspect of the disclosure.

FIG. 7 is a block diagram showing an exemplary wireless communication system in which a configuration of the disclosure may be advantageously employed.

FIG. 8 is a block diagram illustrating a design workstation used for circuit, layout, and logic design of a semiconductor component according to one configuration.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent to those skilled in the art, however, that these concepts may be practiced without these specific details. In some instances, well-known structures and components are shown in block diagram form in order to avoid obscuring such concepts. As described herein, the use of the term “and/or” is intended to represent an “inclusive OR”, and the use of the term “or” is intended to represent an “exclusive OR”.

Semiconductor fabrication processes are often divided into three parts: a front end of line (FEOL), a middle of line (MOL) and a back end of line (BEOL). Front end of line processes include wafer preparation, isolation, well formation, gate patterning, spacers, and dopant implantation. A middle of line process includes gate and terminal contact formation. The gate and terminal contact formation of the middle of line process, however, is an increasingly challenging part of the fabrication flow, particularly for lithography patterning. Back end of line processes include forming interconnects and dielectric layers for coupling to the FEOL devices. These interconnects may be fabricated with a dual damascene process using plasma-enhanced chemical vapor deposition (PECVD) deposited interlayer dielectric (ILD) materials.

More recently, the number of interconnect levels for circuitry has substantially increased due to the large number of transistors that are now interconnected in a modern microprocessor. The increased number of interconnect levels for supporting the increased number of transistors involves more intricate middle of line processes to perform the gate and terminal contact formation.

As described herein, the middle of line interconnect layers may refer to the conductive interconnects for connecting a first conductive layer (e.g., metal 1 (M1)) to the oxide diffusion (OD) layer of an integrated circuit as well for connecting M1 to the active devices of the integrated circuit. The middle of line interconnect layers for connecting M1 to the OD layer of an integrated circuit may be referred to as “MD1” and “MD2.” The middle of line interconnect layer for connecting M1 to the poly (conductive) gates of an integrated circuit may be referred to as “MP.”

For the scaling of static random access memories (SRAMs) to follow Moore's law, SRAM layouts should be designed to allow higher density, higher yield and lower production costs. One example of an SRAM memory cell is a six transistor (6T) SRAM memory cell that includes, for example, six metal-oxide-semiconductor (MOS) transistors. As processes for fabricating MOS devices migrate to smaller and smaller nanometer technologies, the use of conventional 6T SRAM cells within memories prohibits compliance with performance specifications, decreases process margin, and increases manufacturing costs. Furthermore, SRAM designs may employ conductive layers that violate minimum conductive area scaling rules.

One aspect of the present disclosure merges a first conductive layer (e.g., M1) from a first cell with a first conductive layer from a neighboring cell. The vias (e.g., Via1) that couple the first conductive layer (e.g., M1) to a second conductive layer (e.g., M2) within the first cell are omitted in the neighboring cells. In this aspect of the disclosure, the merged first conductive layer may provide a wordline landing pad that is shared between the first cell and the neighboring cell in an adjacent column. This omitting of the vias (e.g., Via0 and Via1) as well as sharing of the merged first conductive layers for neighboring cells in two adjacent columns enables formation of an SRAM memory that complies with the minimum conductive area rule.

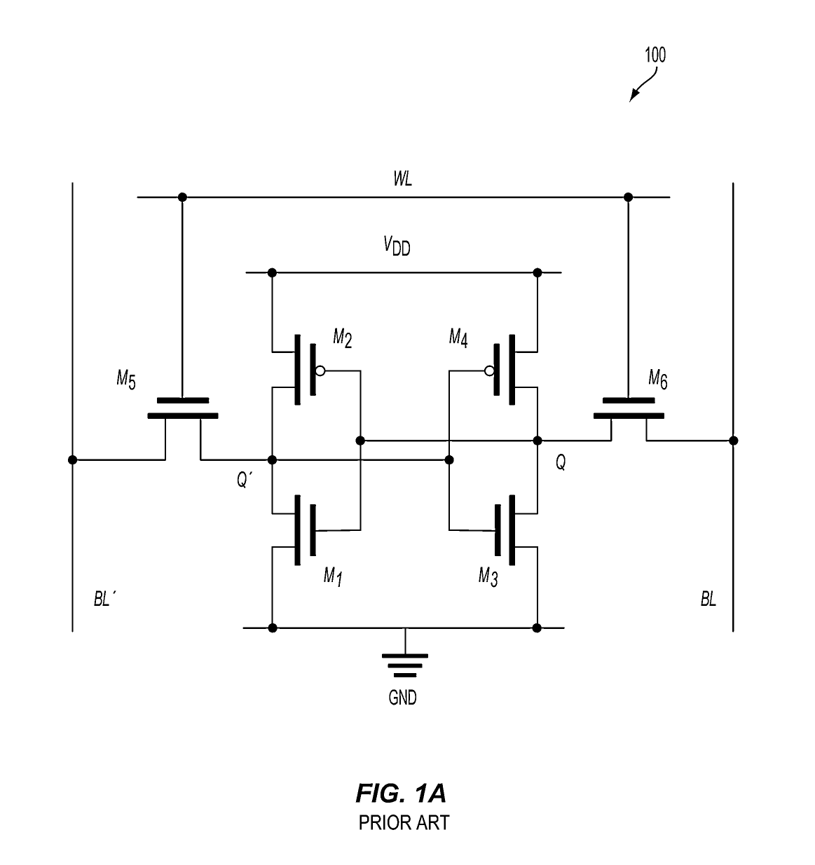

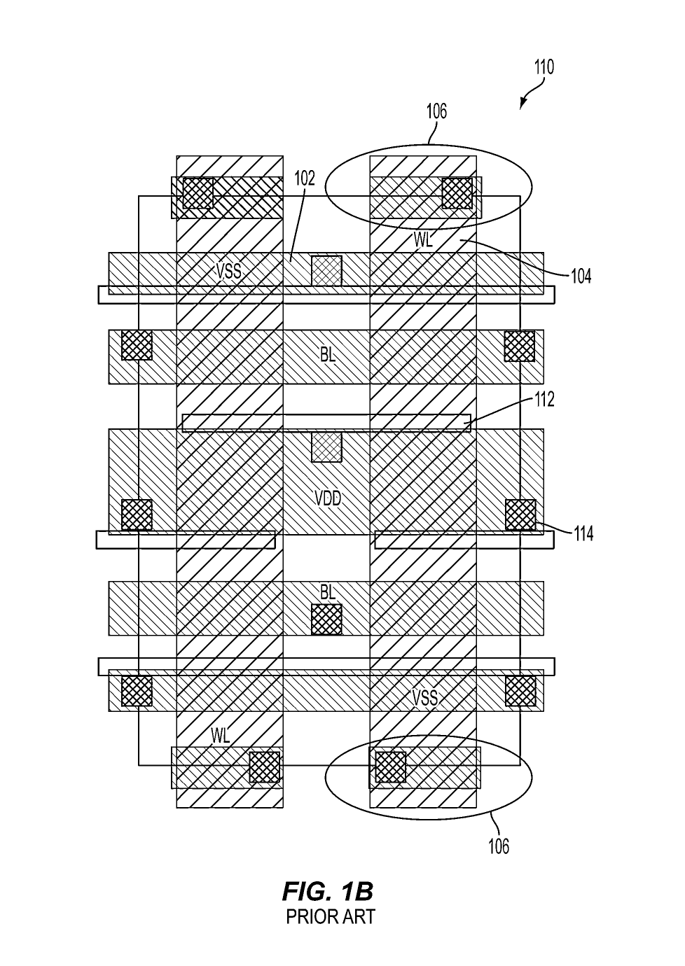

FIG. 1A shows a schematic of a conventional 6T SRAM memory cell. The 6T SRAM cell is made up of six transistors, which may be metal oxide semiconductor field effect transistors (MOSFETs)—M₁, M₂, M₃, M₄, M₅, and M₆. Each bit in an SRAM may be stored on four transistors (M₁, M₂, M₃, M₄) that form a storage cell of two cross-coupled inverters. This storage cell has two stable states—Q and Q′—which denote 0 and 1, or vice versa. Two additional access transistors—M₅ and M₆—serve to control the access to a storage cell during read and write operations.

Access to the cell is enabled by the wordline (WL) which controls the two access transistors M₅ and M₆ which, in turn, control whether the cell should be connected to the bit lines: BL and BL′. They transfer data for both read and write operations.

During read access, the bit lines are actively driven high and low by the inverters in the SRAM cell. This improves SRAM bandwidth compared to dynamic random access memories (DRAMs). In a DRAM, the bit line is connected to storage capacitors and charge sharing causes the bit line to swing upwards or downwards. The symmetric structure of SRAMs also allows for differential signaling, which simplifies detection of smaller voltage swings.

The size of an SRAM with m address lines and n data lines is 2^{m} words, or 2^{m}×n bits. As electronic circuit densities increase and technology advances, for example, in deep sub-micron circuits, skilled designers attempt to increase the use of the design layout and the manufacturability and reliability of the circuit.

The design layout is checked against a set of design rules in a design rule check (DRC). The created design layout conforms to a complex set of design rules in order, for example, to ensure a lower probability of fabrication defects. The design rules specify, for example, how far apart various layers should be, or how large or small various aspects of the layout should be for successful fabrication, given the tolerances and other limitations of the fabrication process. A design rule can be, for example, a minimum spacing amount between geometries and may be closely associated to the technology, fabrication process and design characteristics. Also, different minimum spacing amounts between geometries can be specified for different sizes of geometries. A design rule applicable to the present disclosure is the minimum conductive area scaling rule, which dictates the minimum scaling between conductive areas in an SRAM layout.

FIG. 1B shows a layout view of a conventional 6T SRAM cell design 100. As shown in FIG. 1B, bitcells of an SRAM may be arranged in one or more arrays including a pattern of memory elements. The SRAM cell design 100 includes two conductive layers: a first conductive layer 102 (e.g., metal one (M1)), and a second conductive layer 104 (e.g., metal two (M2)). The SRAM cell design 100 also includes transistor active regions 112 and vias 114. The M1 layer 102 may include the bit line (BL), the supply voltage connection (VDD), the ground voltage connection (VSS), and wordline landing pads 106. The wordline landing pads 106 enable the wordlines to electrically communicate with the pass gate transistors. The second conductive layer 104 may include the wordline (WL).

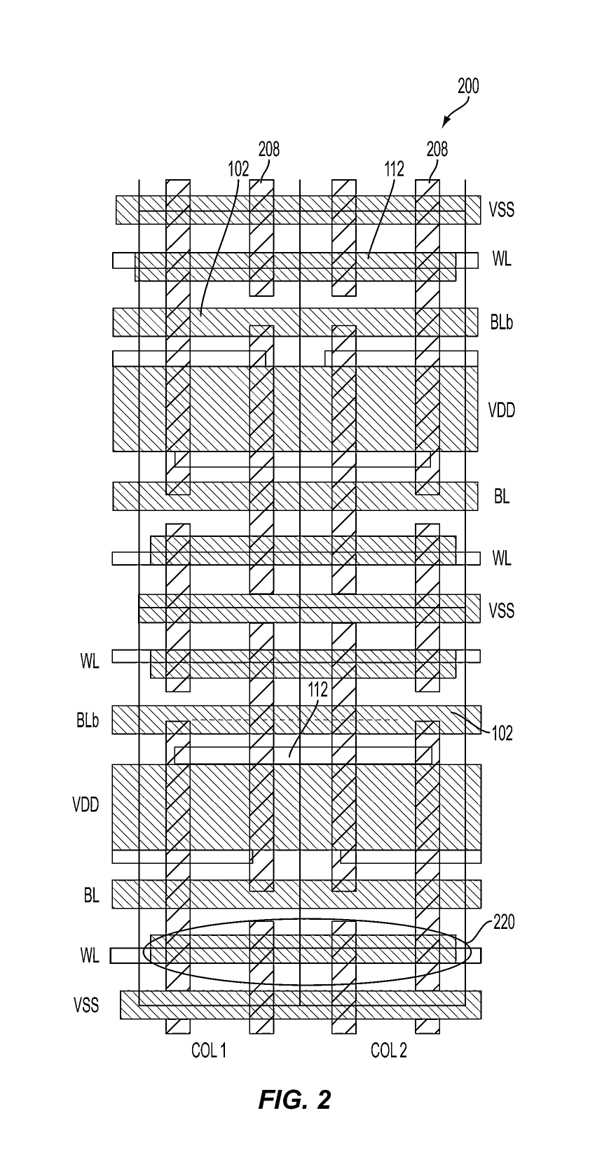

The wordline landing pads 106 may violate the minimum conductive area scaling rule, as discussed above, because they are too small. This violation of the conductive area scaling rule is more likely to occur with aggressive SRAM scaling. One approach to preventing violation of the minimum conductive area scaling rule is to expand the wordline landing pads 106 and allow them to extend into neighboring memory cells. Such an approach is discussed in FIGS. 2, 3, 4A-4B and 5A-5C.

FIG. 2 shows a layout view of an SRAM cell design 200 according to an aspect of the disclosure. The SRAM cell design 200 shown in FIG. 2 is for a 2×2 array of 6T SRAM cells. Each SRAM cell includes conductive gates 208, a first conductive layer 102 (e.g., M1) and transistor active regions 112. The SRAM cell design 200 also shows signals including Vss (ground voltage), WL (wordline), BLb (complimentary bit line (also referred to as BL′)), Vdd (supply voltage), and BL (bit line).

A wordline landing pad provided by the first conductive layer 102 is merged between neighboring SRAM cells in two adjacent columns (column 1 and column 2). In one aspect, the merged wordline landing pad 220 is large enough to comply with SRAM design rules. In a specific example, the merged wordline landing pads are roughly 4000 nm² for a contacted poly pitch (CPP) of roughly sixty-two (62) nanometers in or below a fourteen (14) nanometer technology node. In addition, the bit line capacitance may be reduced by reversing the placement of the merged wordline landing pads 220 and the Vss tracks (Vss) at the first conductive layer 102 (e.g., M1). For example, the merged wordline landing pads 220 are between the bit line (BL) or complimentary bit line (BLb) and Vss, rather than outside of the Vss, as in conventional layouts.

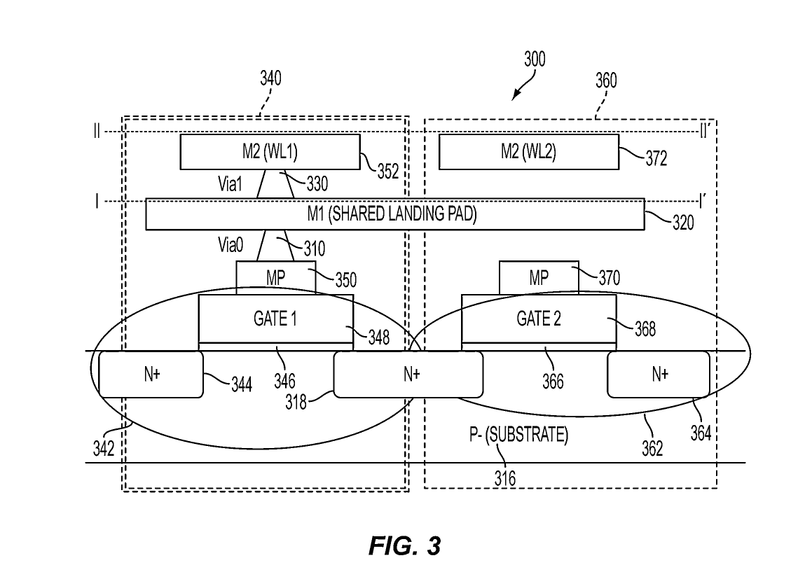

Although the vias are not shown in the SRAM cell design 200, they are discussed in FIGS. 3, 4A-4B and 5A-5C below. For example, as shown in FIG. 3, vias (e.g., Via0) couple the gate contacts (e.g., MP) to the first conductive layer (e.g., M1) in the first cell 340 (e.g., the leftmost cell), and also the wordline to the shared landing pad. Thus, the shared wordline landing pad is coupled to the wordline in the leftmost cell, but not in the second cell 360 (e.g., the rightmost cell). By extending the wordline landing pad into the neighboring cell in an adjacent columns but not coupling it to the wordline, the wordline landing pad is large enough to comply with design constraints. In one aspect of the present disclosure, compliance with the minimum conductive area rule is achieved by sharing the vias (e.g., Via0 and Via1) and merging the first conductive layer (e.g., M1) to provide a wordline landing pad that extends between neighboring cells in two adjacent columns of an SRAM memory.

FIG. 3 shows a cross-sectional view of an SRAM cell design 300 according to an aspect of the disclosure. The SRAM cell design 300 is split into a first cell 340 (e.g., the leftmost cell) and a second cell 360 (e.g., the rightmost cell), as noted by the dashed boxes. The regions enclosed by the dashed boxes may represent a cross-section of a selected column in the SRAM cell design 200 shown in FIG. 2. The common components of both cells include a semiconductor substrate 316 (e.g., a silicon wafer), a shared well 318 and a merged wordline landing pad 320 (e.g., M1). The semiconductor substrate 316 may be a p-type material and the shared well 318 may be an n-type material, or vice versa.

In this configuration, the first cell 340 includes a first transistor 342 having a first conductive gate 348, a first insulating layer 346, a first well 344 and the shared well 318 that border the first cell 340. In addition, a first gate contact 350 (MP) provides access to the first transistor 342. Similarly, the second cell 360 includes a second transistor 362 having a second conductive gate 368, a second insulating layer 366, and a second well and the shared well 318 that border the second cell 360. In addition, a second gate contact 370 (MP) provides access to the second transistor 362.

Although the first cell 340 and the second cell 360 are separate, a first conductive layer (e.g., M1) provides a merged wordline landing pad 320 across both the first cell 340 and the second cell 360. In this configuration, the first cell 340 includes a first via 310 (Via0) that is coupled to the merged wordline landing pad 320 and a second via 330 (e.g., Via1) that couples the merged wordline landing pad 320 to a first wordline 352 (e.g., M2). By contrast, the second cell does not includes either the first via 310 (Via0) or the second via 330 (e.g., Via1) because the merged wordline landing pad 320 is not coupled to either the second gate contact 370 or a second wordline 372 (e.g., M2) of the second cell 360.

In this configuration, the merged wordline landing pad 320 overlaps a neighboring memory cell (e.g., either the first cell 340 or the second cell 360) in an adjacent row of a memory array. In this example, the merged wordline landing pad 320 is electrically isolated from the second gate contact 370 (e.g., MP) of the second cell 360 (e.g., the overlapped cell) by omitting the via in a location corresponding to a location of the first via 310 (Via0) in the first cell 340. The second via 330 (e.g., Via1) couples the first wordline 325 to the shared wordline landing pad of the first conductive layer 306. In operation, the first via 310 (Via0) couples the first conductive gate 348 of the first transistor 342 in the SRAM cell (e.g., the first cell 340) to the merged wordline landing pad 320. The second via 330 (Via1) couples the merged wordline landing pad 320 and the first wordline 352.

The merged wordline landing pad 320 may be fabricated in a self-aligned dual patterning process. Additionally, the first via 310 and the second via 330 may be manufactured in a multiple patterning process. In this configuration, a via (e.g., the first via 310 (Via0)) is omitted from the second gate contact 370 of the second cell 360 of the SRAM cell design 300. In addition, a via (e.g., the second via 330 (Via1)) is omitted from the merged wordline landing pad 320 of the second cell 360 of the SRAM cell design 300. The SRAM cell design 300 may also include a six-transistor (6T) memory cell.

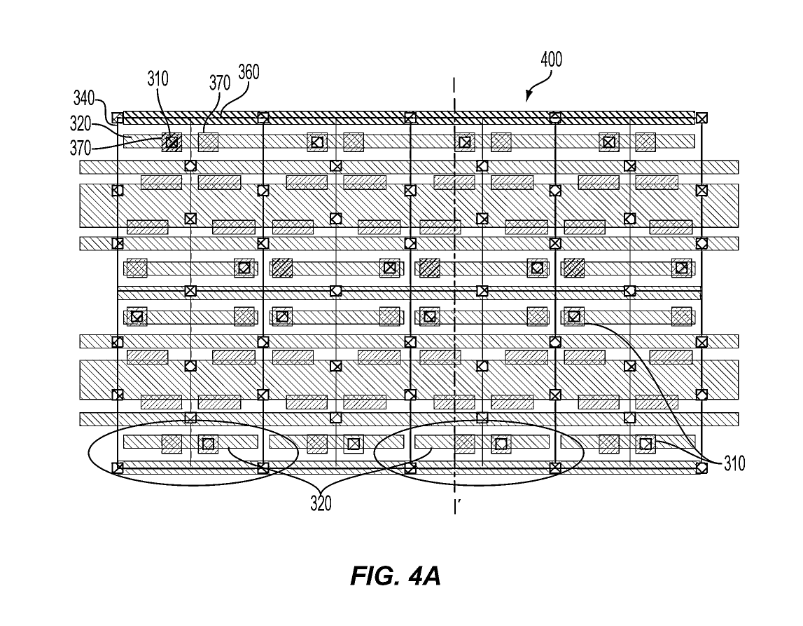

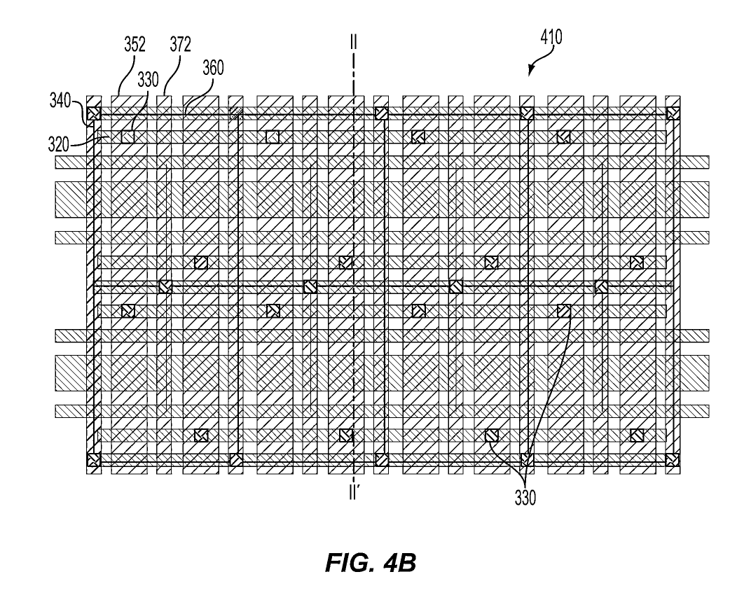

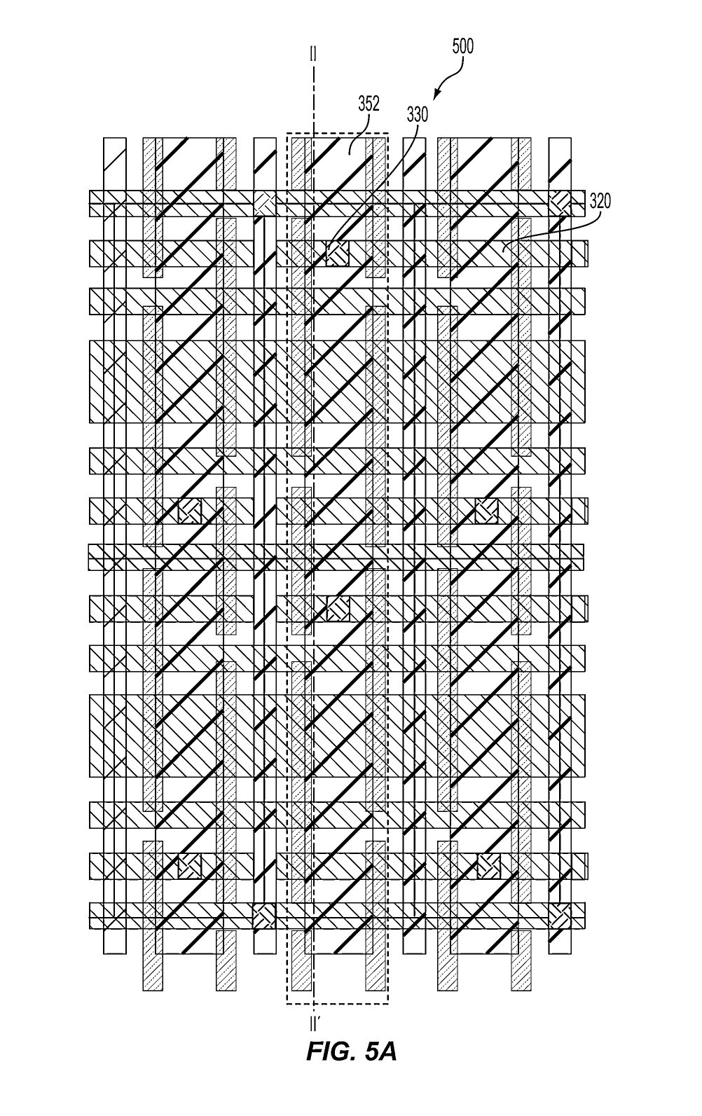

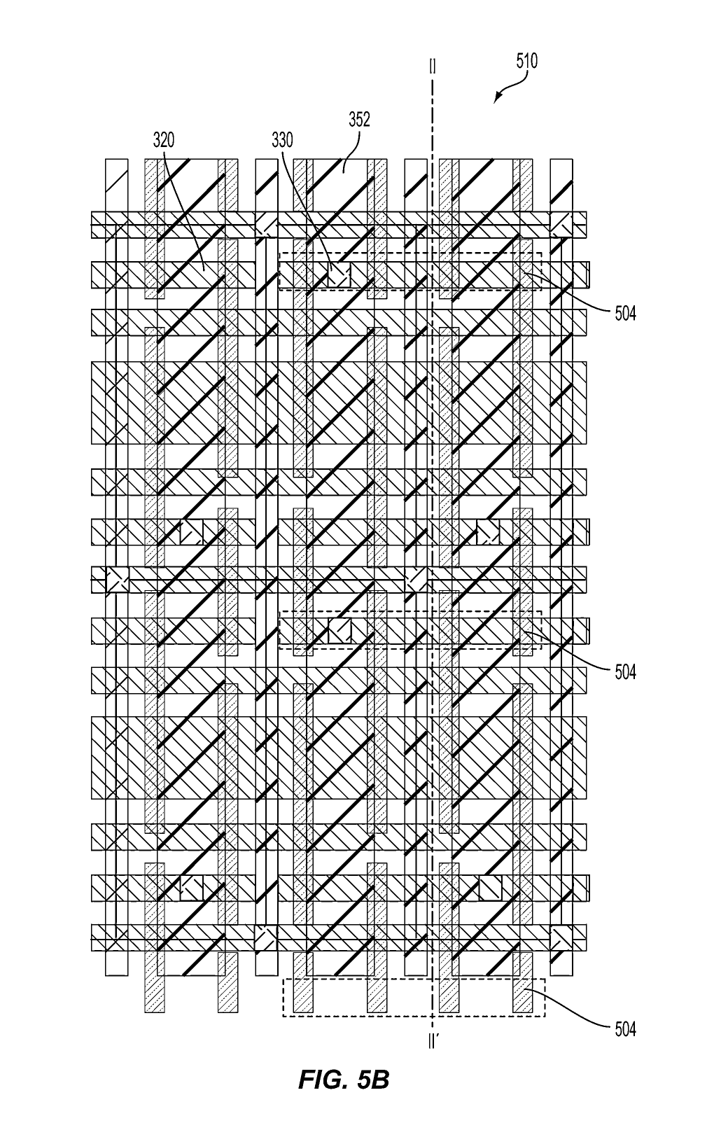

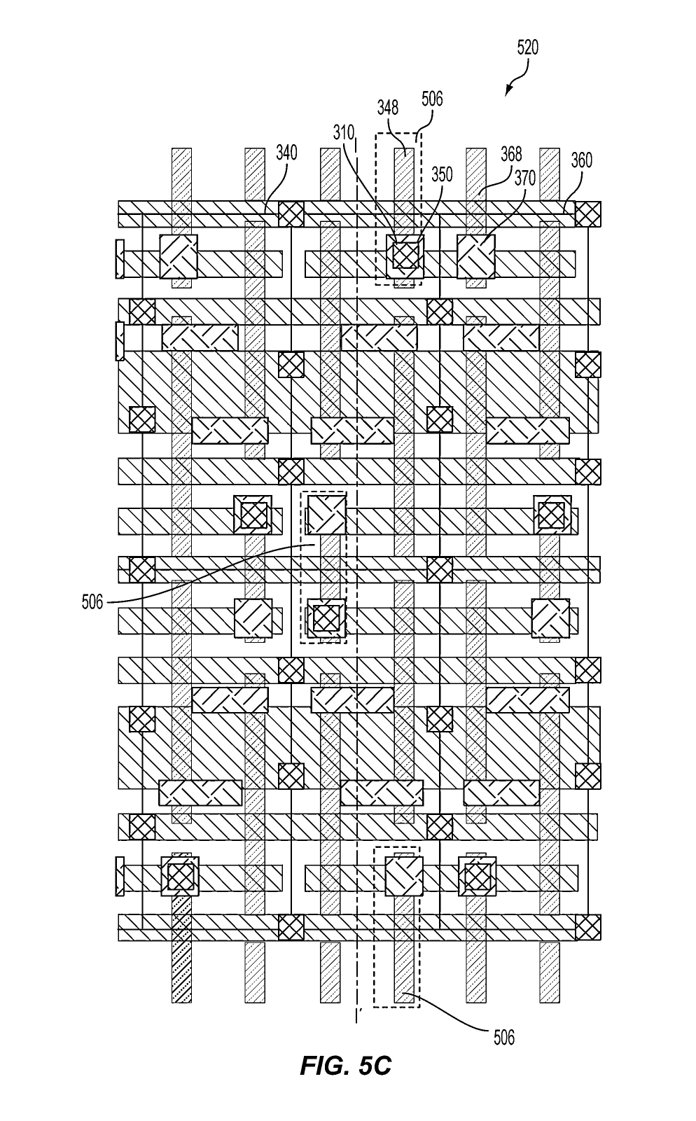

The sectional lines I-I′ and II-IF of FIG. 3 are further described with respect to FIGS. 4A-4B and FIGS. 5A-5C.

FIGS. 4A-4B show top views of the merged wordline landing pads 320, the first vias 310 and the second vias 330 of the SRAM cell designs 400 and 410 according to one aspect of the disclosure. FIG. 4A illustrates the SRAM cell design 400 that makes up the layers of the SRAM cell design 300, as seen from the sectional line I-I′ of FIG. 3 at and below the first conductive layer (e.g., M1) FIG. 4B illustrates the SRAM cell design 410 that makes up the layers of the SRAM cell design 300, as seen from the sectional line II-II′ of FIG. 3 at or below a second conductive layer (e.g., M2).

The SRAM cell design 400 of FIG. 4A shows the merged wordline landing pads 320 of a first conductive layer (e.g., M1), as well as first vias 310 that are omitted in neighboring cells. The SRAM cell design 400 shows components from FIG. 3 including the first cell 340 and the second cell 360. Representatively, the merged wordline landing pad 320 of the first conductive layer (e.g., M1) of the first cell 340 extends into the second cell 360. In addition, the first gate contact 350 (e.g., MP), and the first vias 310 (e.g., Via0) that couple the first gate contact 350 (e.g., MP) to the merged wordline landing pad 320 are shown. The second gate contact 370 of the second cell 360, which is not coupled to the merged wordline landing pad 320 is also shown.

The SRAM cell design 410 of FIG. 4B shows the second vias 330 of the first cell 340 that are omitted in the second cell 360 that neighbors the first cell 340. The SRAM cell design 410 shows components from FIG. 3 including the second conductive layer (e.g., M2, making up the first wordline 352 (WL1) and the second wordline 372 (WL2)), the merged wordline landing pad 320, and the second via 330 for coupling to the first wordline 352 (WL1).

To prevent the merged wordline landing pad 320 from shorting to the second wordline 372 (provided by the second conductive layer M2) on neighboring cells, the vias to the merged wordline pads 406 are skipped on the second gate contacts 370 of alternate cells. For example, each cell may only include one first via 308 for each merged wordline pad 406, even though the pad extends to the neighboring cell.

The first gate contacts 350 may also extend vertically to reach the first vias 310 (Via0) in a vertically adjacent cell. The second vias 330 (Via1) are omitted from the merged wordline landing pad 320 in horizontally adjacent cells. The horizontal direction may be the direction in which the first gate contact 350 extends. The first vias 310 (Via0) are omitted from the second gate contact 370 (FIG. 3) in vertically adjacent cells. The vertical direction may be perpendicular to the direction in which the first gate contacts 350 extend.

FIGS. 5A-5C show wordlines, vias, and gate contacts from layout views of SRAM cell designs 500, 510 and 520 according to aspects of the disclosure. FIG. 5A and FIG. 5B illustrate a propagation example of the SRAM cell designs 500 and 510 that make up the layers of SRAM cell design 300, as seen along the sectional line II-II′ of FIG. 3. FIG. 5C illustrates an SRAM cell design 520 that makes up the layers of the SRAM cell design 300, as seen along the sectional line I-I′ of FIG. 3.

FIG. 5A shows the first step in the signal propagation through the SRAM cell design 500 in one aspect of the present disclosure. In this example, a first wordline 352 (e.g., M2) is activated. The merged wordline landing pad 320 (e.g., M1) and the second via 330 (e.g., Via1) are also shown.

FIG. 5B shows the second step in the signal propagation through the SRAM cell design 510. In this example, horizontal via regions 504 include the second via 330 (e.g., Via1) that is omitted in horizontally adjacent cells. In this configuration, horizontally adjacent cells are coupled to the first wordline 352 (e.g., M2) and the merged wordline landing pad 320 that extends between the two adjacent cells. In this example, the merged wordline landing pads 320 are activated within the horizontal via regions 504.

FIG. 5C shows the next step in the signal propagation through the SRAM cell design 520. In this example, the first cell 340 includes vertical via regions 506 including the first via 310, the first gate contact 350 and the first conductive gate 348. The second cell 360 includes the second conductive gate 368 and the second gate contact 370. In this configuration, the second gate contact 370 is exposed by an omitted via (e.g., the first via 310). Others of the gate contacts are coupled to the merged wordline landing pad 320 (e.g., M1) by the first via 310 (e.g., Via0) that is omitted in one of two vertically adjacent cells. Therefore, each of the first vias 310 (e.g., Via0) are coupled to the first conductive gate 348 that extends into two vertically adjacent cells. In this example, the first conductive gate 348 within the vertical via regions 506 are activated by the first gate contact 350 when the first gate contact 350 is coupled to the merged wordline landing pad 320 by the first vias 310 (e.g., Via0).

With reference to FIG. 3, FIGS. 4A-4B and FIGS. 5A-5C, the first vias 310 (Via0) couples the first gate contact 350 to the merged wordline landing pad 320 provided by the first conductive layer (M1) between neighboring cells. The second vias 330 (Via1) couple the merged wordline landing pad 320 to the first wordline 352. In this configuration, the second conductive layer M2 provides wordlines for each of the cells.

In one configuration, the above-described directions of horizontal or vertical are not limited to the directions described, and can instead be any direction from any point of reference. For example, all horizontal orientations can be vertical, and vice versa.

Improvements brought about by aspects of the present disclosure include having a merged first conductive layer (e.g., M1) that allows for a larger first conductive area for an aggressively scaled contacted poly pitch (CPP). A first via (Via0) pattern also allows a 2-step process (e.g., double patterning) for manufacturing the first vias, reducing a mask count and cost. A second via (Via1) process also allows a 2-step process for manufacturing the second vias, reducing a mask count and cost. In another aspect, placement of Vss and wordline pads at the first conductive layer M1 is reversed to make the bit line capacitance much smaller than existing SRAM memory cell designs.

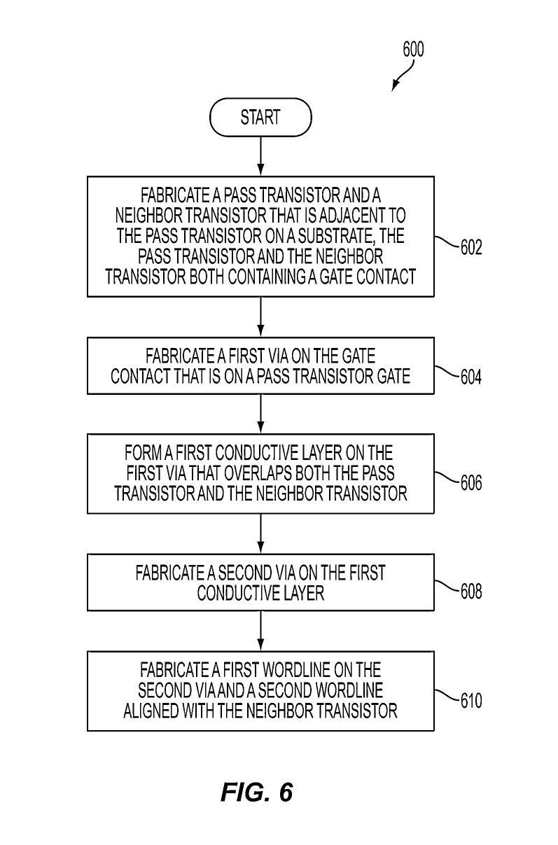

FIG. 6 is a process flow diagram illustrating a process 600 of fabricating an SRAM memory cell design according to an aspect of the disclosure. In block 602, a pass transistor (e.g., first transistor 342) and a neighbor transistor (e.g., second transistor 362) that is adjacent to the pass transistor are fabricated on a substrate (e.g., the semiconductor substrate 316). The pass transistor and the neighbor transistor both contain a gate contact (e.g., the first gate contact 350 and the second gate contact 370) on their conductive gates. In block 604, a first via (e.g., first via 310 (Via0)) is fabricated on the gate contact of a pass transistor gate. In block 606, a first conductive layer (e.g., the merged wordline landing pad 320) is formed on the first via and also overlaps both the pass transistor and the neighbor transistor.

In block 608, a second via (e.g., second via 330 (Via1)) is fabricated on the first conductive layer. In block 610, a first wordline (e.g., the first wordline 352) is fabricated on the second via, and a second wordline (e.g., the second wordline 372) is fabricated on the neighbor transistor.

In one configuration, fabricating the pass transistor and the neighbor transistor on the substrate includes forming at least two material wells in the substrate, and fabricating an insulating layer over the material wells. Fabricating the pass transistor and the neighbor transistor on the substrate also includes fabricating a gate over the insulating layer. In one configuration, a layer of interlayer dielectric material separates the gate contact on a neighbor transistor gate and the first conductive layer. A layer of interlayer dielectric material may also separate the first conductive layer and the second wordline. The first wordline and the second wordline may be fabricated from a second conductive layer.

In one aspect, a static random access memory (SRAM) cell, includes a first conductive layer providing a wordline landing pad extending into a neighboring memory cell in an adjacent row of a memory array. The SRAM cell further includes a first means for coupling a gate contact of a pass transistor gate in the SRAM cell to the wordline landing pad in the first conductive layer. The SRAM cell also includes a second means for coupling the wordline landing pad and the wordline of the second conducting means. In one aspect, the first coupling means can be the first via 310 (Via0). The second coupling means may be the second via 330 (Via1). In another aspect, the aforementioned means may be any material or structure configured to perform the functions recited by the aforementioned means.

In one configuration, the conductive material used for the various conductive layers including the first conductive layer M1, the second conductive layer M2, and the gate contact may be copper (Cu), or other conductive materials with high conductivity. Alternatively, the conductive material may include copper (Cu), silver (Ag), annealed copper (Cu), gold (Au), aluminum (Al), calcium (Ca), tungsten (W), zinc (Zn), nickel (Ni), lithium (Li) or iron (Fe). The aforementioned conductive material layers may also be deposited by electroplating, chemical vapor deposition (CVD), physical vapor deposition (PVD), sputtering, or evaporation.

The first insulating layer 346 and the second insulating layer 366 may be made of materials having a low k, or a low dielectric constant value, including silicon dioxide (SiO₂) and fluorine-doped, carbon-doped, and porous carbon-doped forms, as well as spin-on organic polymeric dielectrics such as polyimide, polynorbornenes, benzocyclobutene (BCB) and polytetrafluoroethylene (PTFE), spin-on silicone based polymeric dielectrics and silicon nitrogen-containing oxycarbides (SiCON).

Although not mentioned in the above process steps, photoresist, ultraviolet exposure through masks, photoresist development and lithography may be used. Photoresist layers may be deposited by spin-coating, droplet-based photoresist deposition, spraying, chemical vapor deposition (CVD), physical vapor deposition (PVD), sputtering, or evaporation. Photoresist layers may then be exposed and then etched by chemical etching processes using solutions such as Iron Chloride (FeCl₃), Cupric Chloride (CuCl₂) or Alkaline Ammonia (NH₃) to wash away the exposed photoresist portions, or dry etching processes using plasmas. Photoresist layers may also be stripped by a chemical photoresist stripping process or a dry photoresist stripping process using plasmas such as oxygen, which is known as ashing.

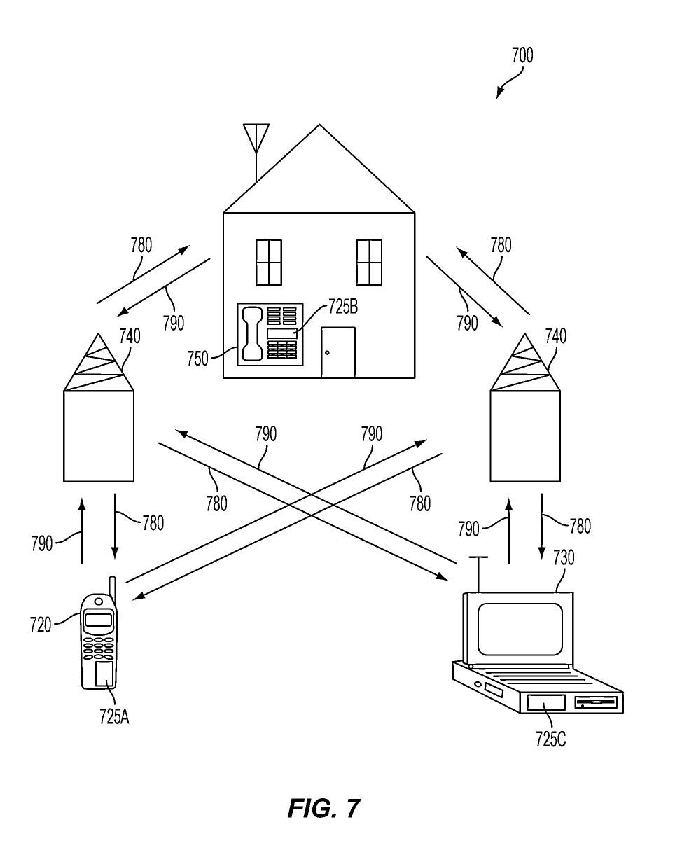

FIG. 7 is a block diagram showing an exemplary wireless communication system 700 in which an aspect of the disclosure may be advantageously employed. For purposes of illustration, FIG. 7 shows three remote units 720, 730, and 750 and two base stations 740. It will be recognized that wireless communication systems may have many more remote units and base stations. Remote units 720, 730, and 750 include IC devices 725A, 725C, and 725B that include the disclosed devices (e.g., devices having shared wordline landing pads). It will be recognized that other devices may also include the disclosed devices (e.g., devices having shared wordline landing pads), such as the base stations, switching devices, and network equipment. FIG. 7 shows forward link signals 780 from the base station 740 to the remote units 720, 730, and 750 and reverse link signals 790 from the remote units 720, 730, and 750 to base stations 740.

In FIG. 7, remote unit 720 is shown as a mobile telephone, remote unit 730 is shown as a portable computer, and remote unit 750 is shown as a fixed location remote unit in a wireless local loop system. For example, the remote units may be mobile phones, hand-held personal communication systems (PCS) units, portable data units such as personal data assistants, GPS enabled devices, navigation devices, set top boxes, music players, video players, entertainment units, fixed location data units such as meter reading equipment, or other devices that store or retrieve data or computer instructions, or combinations thereof. Although FIG. 7 illustrates remote units according to the aspects of the disclosure, the disclosure is not limited to these exemplary illustrated units. Aspects of the disclosure may be suitably employed in many devices, which include the disclosed devices.

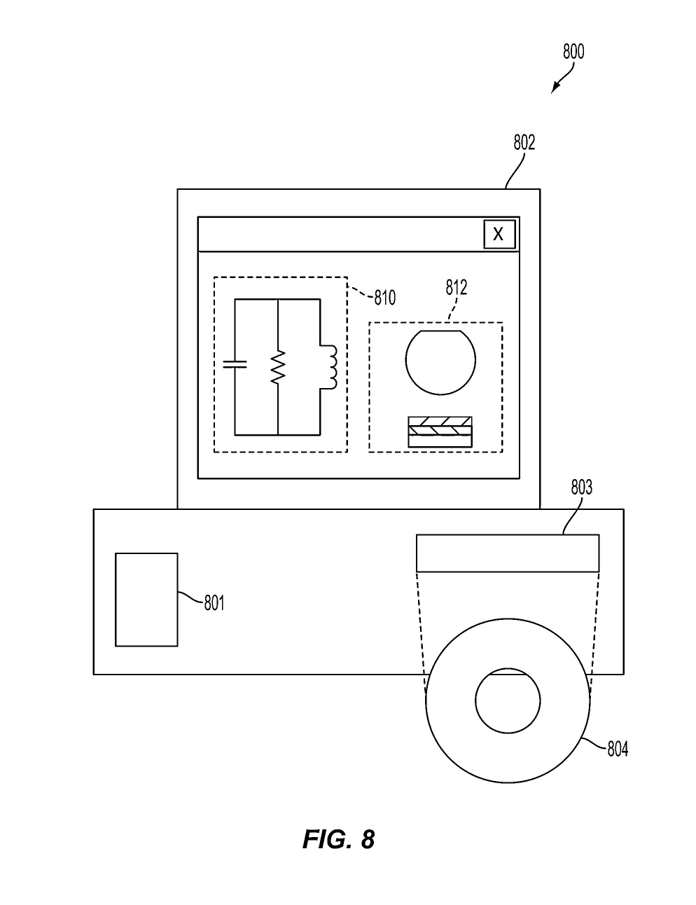

FIG. 8 is a block diagram illustrating a design workstation 800 used for circuit, layout, and logic design of a semiconductor component, such as the devices disclosed above containing shared wordline landing pads. A design workstation 800 includes a hard disk 801 containing operating system software, support files, and design software such as Cadence or OrCAD. The design workstation 800 also includes a display 802 to facilitate design of a circuit 810 or a semiconductor component 812 such as the disclosed device (e.g., device having shared wordline landing pads). A storage medium 804 is provided for tangibly storing the circuit design 810 or the semiconductor component 812. The circuit design 810 or the semiconductor component 812 may be stored on the storage medium 804 in a file format such as GDSII or GERBER. The storage medium 804 may be a CD-ROM, DVD, hard disk, flash memory, or other appropriate device. Furthermore, the design workstation 800 includes a drive apparatus 803 for accepting input from or writing output to the storage medium 804.

Data recorded on the storage medium 804 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 804 facilitates the design of the circuit design 810 or the semiconductor component 812 by decreasing the number of processes for designing semiconductor wafers or dies.

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer; disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

What is claimed is:

1. A static random access memory (SRAM) cell, comprising:
a first conductive layer including a wordline landing pad extending into a neighboring memory cell in an adjacent row of a memory array, the wordline landing pad in the first conductive layer being electrically isolated from all gate contacts of the neighboring memory cell;
a second conductive layer including a wordline coupled to the wordline landing pad in the first conductive layer;
a first via coupling a gate contact of a pass transistor gate in the SRAM cell to the wordline landing pad in the first conductive layer; and
a second via coupling the wordline landing pad and the wordline of the second conductive layer.

2. The SRAM cell of claim 1, in which the first conductive layer including the wordline landing pad is fabricated with a self-aligned dual patterning process.

3. The SRAM cell of claim 1, in which the first via and the second via are manufactured in a multiple patterning process.

4. The SRAM cell of claim 1, in which the via in a location corresponding to a first via location is omitted in the neighboring memory cell.

5. The SRAM cell of claim 1, comprising a six-transistor memory cell.

6. The SRAM cell of claim 1 incorporated into at least one of a music player, a video player, an entertainment unit, a navigation device, a communications device, a personal digital assistant (PDA), a fixed location data unit, and a computer.

7. A method of fabricating a semiconductor device comprising:
fabricating a pass transistor and a neighbor transistor that is adjacent to the pass transistor on a substrate, the pass transistor and the neighbor transistor both containing a gate contact;
fabricating a first via on the gate contact that is on a pass transistor gate;
forming a first conductive layer on the first via that overlaps both the pass transistor and the neighbor transistor;
fabricating a second via on the first conductive layer; and
fabricating a first wordline on the second via and a second wordline aligned with the neighbor transistor.

8. The method of claim 7, in which fabricating the pass transistor and the neighbor transistor on the substrate comprises:
forming at least two material wells in the substrate;
fabricating an insulating layer over the at least two material wells; and
fabricating a conductive gate on the insulating layer.

9. The method of claim 7, in which a layer of interlayer dielectric material separates the gate contact on the neighbor transistor and the first conductive layer.

10. The method of claim 7, in which a layer of interlayer dielectric material separates the first conductive layer and the second wordline.

11. The method of claim 7, in which the first wordline and the second wordline are fabricated from a second conductive layer.

12. The method of claim 7, further comprising incorporating the semiconductor device into at least one of a music player, a video player, an entertainment unit, a navigation device, a communications device, a personal digital assistant (PDA), a fixed location data unit, and a computer.

13. A static random access memory (SRAM) cell, comprising:
a first conductive layer including a wordline landing pad extending into a neighboring memory cell in an adjacent row of a memory array, the wordline landing pad in the first conductive layer being electrically isolated from all gate contacts of the neighboring memory cell;
a second conductive layer including a wordline coupled to the wordline landing pad in the first conductive layer;
a first means for coupling a gate contact of a pass transistor gate in the SRAM cell to the wordline landing pad in the first conductive layer; and
a second means for coupling the wordline landing pad and the wordline of the second conductive layer.

14. The SRAM cell of claim 13, in which the first conducting layer including the wordline landing pad is fabricated with a self-aligned dual patterning process.

15. The SRAM cell of claim 13, in which the first coupling means and the second coupling means are manufactured in a multiple patterning process.

16. The SRAM cell of claim 13, in which a via in a location corresponding to a location of the first means is omitted in the neighboring memory cell.

17. The SRAM cell of claim 13, comprising a six-transistor memory cell.

18. The SRAM cell of claim 13 incorporated into at least one of a music player, a video player, an entertainment unit, a navigation device, a communications device, a personal digital assistant (PDA), a fixed location data unit, and a computer.

19. A method of fabricating a semiconductor device comprising the steps of:
fabricating a pass transistor and a neighbor transistor that is adjacent to the pass transistor on a substrate, the pass transistor and the neighbor transistor both containing a gate contact;
fabricating a first via on the gate contact that is on a pass transistor gate;
forming a first conductive layer on the first via that overlaps both the pass transistor and the neighbor transistor;
fabricating a second via on the first conductive layer; and
fabricating a first wordline on the second via and a second wordline aligned with the neighbor transistor.

20. The method of claim 19, further comprising the step of incorporating the semiconductor device into at least one of a music player, a video player, an entertainment unit, a navigation device, a communications device, a personal digital assistant (PDA), a fixed location data unit, and a computer.
